(19) United States
(12) Patent Application Publication
(10) Pub. No.: US 2020/0219739 A1
(43) Pub. Date: Jul. 9, 2020

(54) SUBSTRATE TEMPERATURE MEASUREMENT DEVICE AND AN APPARATUS HAVING SUBSTRATE TEMPERATURE MEASUREMENT DEVICE

(71) Applicant: NISSIN ION EQUIPMENT CO., LTD., Kyoto-shi (JP)

(72) Inventors: Ryosuke GOTO, Kyoto (JP); Masatoshi ONODA, Kyoto (JP)

(73) Assignee: NISSIN ION EQUIPMENT CO., LTD., Kyoto-shi (JP)

(21) Appl. No.: 16/723,235

(22) Filed: Dec. 20, 2019

(30) Foreign Application Priority Data
Jan. 8, 2019 (JP) 2019-1480
Jun. 20, 2019 (JP) 2019-114375

(51) Int. Cl. H01L 21/67; H01J 37/317; G01K 1/14; H05B 1/02

(52) U.S. Cl. CPC H01L 21/67248; H01J 37/3171; H01J 2237/24585; H05B 1/0233; G01K 1/143

(57) ABSTRACT

A device is provided. The device includes a body, a heat absorber, a test piece and a contact thermometer. The heat absorber is attached to the body. The test piece is attached to the body and spaced apart from the heat absorber. The test piece has an overlap region that is overlapped by the heat absorber such that the heat absorber absorbs heat radiated toward the device and a non-overlap region which does not overlap with the heat absorber and which is exposed to the heat radiated toward the device. The contact thermometer is coupled to the overlap region. The test piece has a thermal transmissivity approximately equal to that of a substrate, and the device positions the overlap region of the test piece adjacent to the substrate being radiated by the heat.

### CROSS-REFERENCE TO RELATED APPLICATION

This application claims priority from Japanese Patent Application No. JP2019-1480, filed in the Japanese Patent Office on Jan. 8, 2019, and Japanese Patent Application No. JP2019-114375, filed in the Japanese Patent Office on Jun. 20, 2019, the entire contents of each of which is incorporated by reference herein in their entireties.

### BACKGROUND

### 1. Field

The present disclosure relates to a substrate temperature measurement device for use in temperature measurement of a heated substrate and relates to an apparatus having the substrate temperature measurement device.

### 2. Description of Related Art

A semiconductor manufacturing apparatus is used with the process of heating the substrate before/after or during substrate processing, depending on the content of the substrate processing. During this heating process, temperature measurement of the substrate is conducted using a measurement device such as a thermocouple.

JP H04-218670A proposes a technique of measuring the substrate temperature using a radiation thermometer instead of the thermocouple. The reason for using the radiation thermometer instead of the thermocouple includes a situation where, in a substrate capable of transmitting infrared rays therethrough, such as a silicon substrate, the thermocouple is undesirably heated by infrared rays transmitted through the substrate, and thereby accurate temperature measurement becomes impossible.

### SUMMARY

It is an aspect to provide a substrate temperature measurement device capable of accurately measuring the temperature of a substrate using a contact thermometer, like a thermocouple.

According to an aspect of one or more embodiments, there is provided a device comprising a test piece having a thermal transmissivity approximately equal to that of a substrate; a device body to which the probe member is attached; and a heat absorbing member attached to the device body in spaced-apart relation to the test piece in a first direction, wherein the test piece has an overlap region which overlaps the heat absorbing member in the first direction, and a non-overlap region which does not overlap the heat absorbing member in the first direction, and wherein the non-overlap region is exposed to a heat source, and the overlap region has a contact thermometer attached thereto.

According to another aspect of one or more embodiments, there is provided device comprising a body; a heat absorber attached to the body; a piece attached to the body and spaced apart from the heat absorber, the piece having an overlap region that is overlapped by the heat absorber such that the heat absorber absorbs heat radiated toward the device and a non-overlap region which does not overlap with the heat absorber and which is exposed to the heat radiated toward the device; and a contact thermometer coupled to the overlap region, wherein the piece has a thermal transmissivity approximately equal to that of a substrate, and the device is configured to position the overlap region of the piece adjacent to the substrate being radiated by the heat.

### BRIEF DESCRIPTION OF THE DRAWINGS

The above and/or other aspects will become apparent and more readily appreciated from the following description of embodiments, taken in conjunction with the accompanying drawings of which:

FIG. 1 is a perspective view showing a substrate temperature measurement device according to an embodiment;

FIG. 2 is a plan view showing an example of a state in which the substrate temperature measurement device is used inside a semiconductor manufacturing apparatus, according to an embodiment;

FIG. 3 is a perspective view showing an example of a configuration of the substrate temperature measurement device, according to an embodiment;

FIGS. 4A and 4B are a plan view and a top view, respectively, showing an example in which substrate temperature measurement devices are two-dimensionally arranged, according to an embodiment;

FIG. 5 is a plan view showing an example of a configuration of an ion implantation apparatus equipped with a substrate temperature measurement device, according to an embodiment;

FIGS. 6A and 6B are plan views showing two examples of a configuration of a substrate temperature measurement device, wherein a device body of the substrate temperature measurement device is configured to be swingable, according to embodiments;

FIG. 7 is a plan view showing an example of a configuration of an ion implantation apparatus equipped with a substrate temperature measurement device, according to an embodiment; and

FIG. 8 is a perspective view showing a substrate temperature measurement device according to an embodiment.

### DETAILED DESCRIPTION

The embodiments of the present disclosure may be diversely modified. However, it is to be understood that the present disclosure is not limited to a specific embodiment, but includes all modifications, equivalents, and substitutions of embodiments disclosed herein without departing from the scope and spirit of the present disclosure and claims.

Generally, a radiation thermometer is disposed outside a vacuum chamber in which a substrate is being subjected to a heating process, because the radiation thermometer cannot withstand high temperatures well and thus is low in terms of heatproof temperature, as compared with a contact thermometer such as a thermocouple.

A measurement of a temperature of the substrate by the radiation thermometer is performed through a view port provided in a wall of the vacuum chamber. However, this configuration involves a restriction regarding an installation location of the view port itself and spatial restrictions such as a restriction that an obstacle must not be disposed between the substrate and the view port. Thus, it is advantageous to use a contact thermometer exemplified by a thermocouple, which is free of such restrictions.

However, as mentioned in JP H04-218670A, depending on a combination of a substrate and a heat source, the thermocouple is undesirably heated by the heat source. Thus, it has been believed that it is impossible for the thermocouple to realize accurate temperature measurement.

Exemplary embodiments provide a substrate temperature measurement device capable of accurately measuring the temperature of a substrate using a contact thermometer.

According to an aspect of one or more embodiments, a substrate temperature measurement device for use in temperature measurement of a substrate heated by a heat source includes a test piece having a thermal transmissivity approximately equal to that of the substrate, a device body to which the test piece is attached, and a heat absorbing member attached to the device body in spaced-apart relation to the test piece in a first direction. The test piece has an overlap region which overlaps the heat absorbing member in the first direction, and a non-overlap region which does not overlap the heat absorbing member in the first direction. The non-overlap region is exposed to the heat source, and the overlap region has a contact thermometer attached thereto.

According to this configuration, instead of measuring the substrate temperature directly by a contact thermometer, the test piece having a thermal transmissivity approximately equal to that of the substrate is provided, and the contact thermometer is attached to the overlap region of the test piece overlapping the heat absorbing member, so that it is possible to prevent the contact thermometer from being heated by the heat source.

This configuration makes it possible to accurately measure the substrate temperature, as compared with a related art device in which the contact thermometer is heated by the heat source.

With a view to more accurately performing the temperature measurement, it is advantageous that the contact thermometer includes at least one pair of contact thermometers.

By attaching the at least one pair of contact thermometers, it becomes possible to employ a technique of calculating the amount of heat applied to the test piece, based on a temperature difference between measurement points, and identifying the substrate temperature based on the calculated heat amount.

In a case where the process of heating a substrate is successively performed plural times, it is advantageous to keep the temperature of the test piece at a given value, so as to ensure a uniform state of the test piece before heating.

In view of this, the device body is advantageously provided with a cooling member for cooling the test piece.

Considering degradation of the test piece, it is undesirable that the non-overlap region of the test piece is continued to be exposed to the heat source. Therefore, the device body is advantageously configured to be swingable.

According to another aspect of one or more example embodiments, there is provided a semiconductor manufacturing apparatus including a heat source for heating a substrate during conveyance within a conveyance passage via which the substrate is conveyed, a conveyance mechanism for conveying the substrate in a given direction across the heat source; and the above substrate temperature measurement device which is provided plurally and disposed in opposed relation to the heat source. The substrate temperature measurement devices are arranged side-by-side in the given direction.

In this configuration, when the substrate is conveyed across the heat source, the amount of heat received from the heat source is changed according to the position of the substrate. This heat amount becomes larger as a distance between the substrate and the heat source becomes smaller. On the other hand, the heat amount becomes smaller as the distance between the substrate and the heat source becomes larger.

Therefore, the substrate temperature measurement devices are arranged side-by-side in the conveyance direction of the substrate. This configuration makes it possible to measure the amount of heat applied to the substrate, and the substrate temperature, at different positions in the conveyance direction of the substrate. Thus, by, for example, averaging results of this measurement, it becomes possible to accurately measure the temperature of the substrate conveyed across the heat source, and the amount of heat applied to the substrate.

Further, according to another aspect of one or more embodiments, in view of reducing the number of the substrate temperature measurement devices, there is provided a semiconductor manufacturing apparatus which includes a heat source for heating a substrate during conveyance, a conveyance mechanism for conveying the substrate in a given direction across the heat source, and the above substrate temperature measurement device. The substrate temperature measurement device is configured to be conveyed across the heat source together with the substrate.

According to this configuration, it is possible to accurately identify the temperature of the substrate conveyed across the heat source, as with the aforementioned apparatus in which the substrate temperature measurement devices are arranged side-by-side in the conveyance direction, and measure the substrate temperature and the heat amount over a wide range by a fewer number of the substrate temperature measurement devices, as compared to the aforementioned apparatus in which the substrate temperature measurement devices are arranged side-by-side in the conveyance direction.

According to this configuration, instead of measuring the substrate temperature directly by a contact thermometer, the test piece having a thermal transmissivity approximately equal to that of the substrate is provided, and the contact thermometer is attached to the overlap region of the test piece overlapping the heat absorbing member, so that it is possible to prevent the contact thermometer from being heated by the heat source.

This configuration makes it possible to accurately measure the substrate temperature, as compared with the conventional device in which the contact thermometer is heated by the heat source.

Various exemplary embodiments will now be described with reference to the drawings.

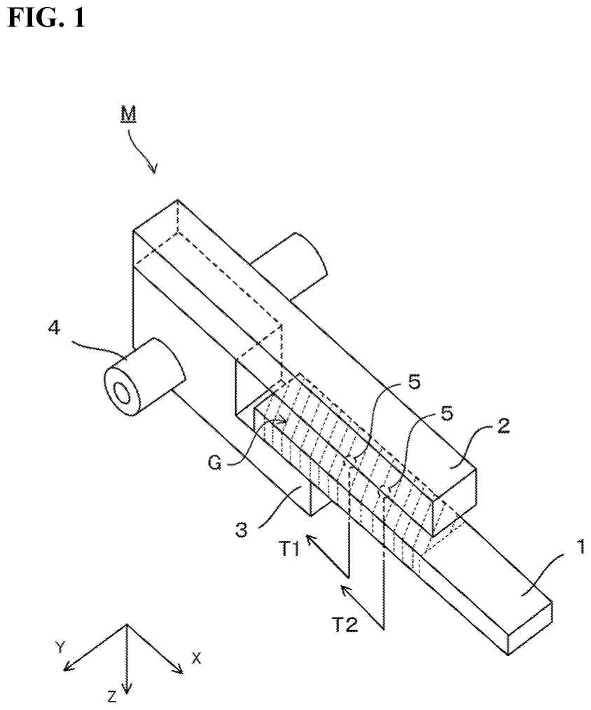

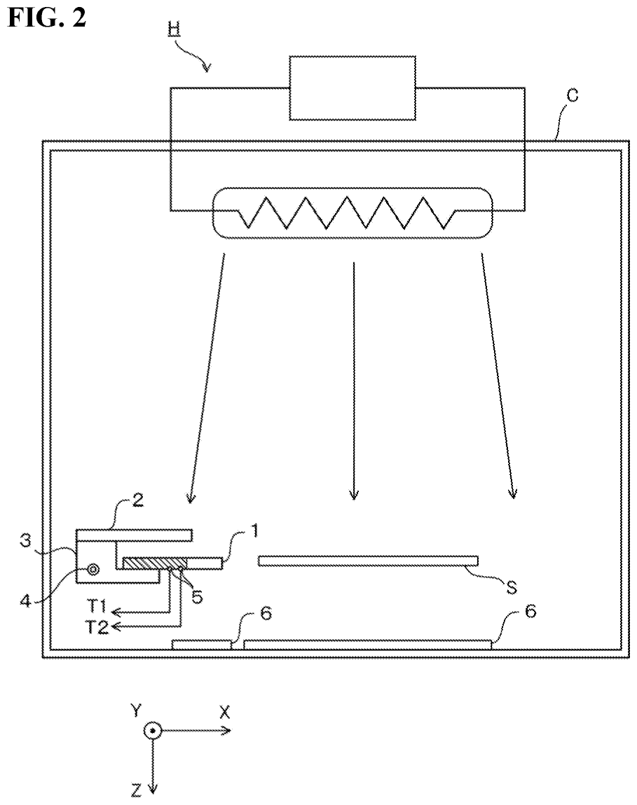

FIG. 1 is a perspective view showing a substrate temperature measurement device according to an embodiment, and FIG. 2 is a plan view showing a example of a state in which the substrate temperature measurement device is used inside a semiconductor manufacturing apparatus, according to an embodiment. With reference to FIGS. 1 and 2, the configuration of the substrate temperature measurement device M will now be described.

It should be noted here that, in FIG. 2, the illustration of a support member for supporting the substrate temperature measurement device M and a substrate S is omitted for conciseness and clarity.

Referring first to FIG. 2, the substrate temperature measurement device M may be disposed inside a vacuum chamber C at a position adjacent to the substrate S, and used for temperature measurement of the substrate heated by a heat source H.

The substrate temperature measurement device M may include a device body 3, a test piece 1, and a heat absorbing member 2. In some embodiments, the test piece may be, for example, a probe, a piece, or a fragment. Each of the test piece 1 and the heat absorbing member 2 is threadingly engaged with or fittingly engaged with the device body 3, wherein the test piece 1 and the heat absorbing member 2 are arranged in a spaced-apart relation in a Z-direction, as illustrated in FIGS. 1 and 2.

The test piece 1 may have an overlap region G which overlaps the heat absorbing member 2 in the Z-direction (a region hatched by broken lines in FIG. 1), and a non-overlap region which does not overlap the heat absorbing member 2 in the Z-direction (the remaining region of the test piece 1 other than the overlap region G, i.e., the non-hatched region in FIG. 1).

Examples of a material constituting the heat absorbing member 2 include a carbon material excellent in heat absorbability and heat resistance, and a high-melting-point material excellent in heat absorbability.

When the substrate is heated by the heat source H from above the heat absorbing member 2, as illustrated in FIG. 2, the non-overlap region of the test piece 1 exposed to the the heat source H is heated. The heat source H may be, for example, an indirect resistance heating-type heat source such as a halogen lamp or an LED lamp.

A main wavelength for use in substrate heating varies depending on the type of heat source. Further, transmissivity with respect to a specific wavelength varies depending on the type of substrate.

The test piece 1 has a thermal transmissivity approximately equal to that of the substrate S such that that the test piece 1 and the substrate S are approximately identical in terms of transmissivity with respect to the main wavelength of heat rays emitted from the heat source H. In some embodiments, a material composition of the test piece 1 may be approximately identical to that of the substrate S. Here, “approximately identical” means a material of the test piece 1 and a material of the substrate have a transmissivity difference of up to about 0.1. In other embodiments, a material composition of the test piece 1 may be partly different from that of the substrate. For example, in some embodiments, the test piece 1 may be formed of about 90% of the same material with the substrate S and about 10% of other materials. In other embodiments, the test piece 1 may be formed of a different material from the substrate S where the different material has a similar thermal transmissivity specification with the substrate S. However, in still other embodiments, the test piece 1 may be formed of an identical material as the substrate S.

When the substrate S is heated by the heat source H, the test piece 1 is heated to the same temperature as that of the substrate S as a measurement target. That is, according to various embodiments, the temperature of the test piece 1 is measured, instead of measuring the substrate temperature. Specifically, one pair of contact thermometers 5 (e.g., thermocouples or thermistors) are attached to the overlap region G of the test piece 1 which overlaps the heat absorbing member 2 in the Z-direction and are used to measure the temperature of the test piece 1.

The overlap region G of the test piece 1 is hidden behind the heat absorbing member 2, and is thereby not directly heated by the heat source H. Thus, by attaching the contact thermometers 5 to the overlap region G and using the contact thermometers 5 so attached to measure the substrate temperature, it becomes possible to more accurately measure the substrate temperature, as compared with a related art device in which the contact thermometers are heated by heat rays transmitted through the substrate.

According to some embodiments, to identify the substrate temperature through the use of one pair of contact thermometers 5, a first technique of determining, as the substrate temperature, a value obtained by averaging two measurement values from the contact thermometers 5, or a second technique of determining, as the substrate temperature, one of the measurement values.

According to some embodiments, when the measurement values are not averaged, the number of the contact thermometers 5 to be attached to the overlap region G of the test piece 1 may be one. Here, the term “one pair of contact thermometers” means two contact thermometers. For example, when the contact thermometer is a thermocouple, the term “one pair of contact thermometers” does not mean one thermocouple having a pair of metal wires, but means two thermocouples each having a separate and distinct structure from the other.

However, in the first and second techniques, a measurement value varies according to a location to which each of the contact thermometer 5 is attached.

Therefore, according to some embodiments, to identify the substrate temperature through the use of one pair of contact thermometers 5, the following technique may be used so as to realize a more accurate temperature measurement.

A heat amount Q (W) to be given to the test piece 1 during heating of the test piece 1 may be calculated from the following formula:

Q=λ·A×(|T1−T2|)/L
where T1 and T2 denote, respectively, temperatures (K) of the test piece 1 measured by the contact thermometers 5; L denotes a distance (m) between measurement points of the contact thermometers 5; λ denotes a thermal conductivity (W/m2·K) of the test piece 1; and A denotes a cross-sectional area (m2) of the test piece 1.

Assuming that the heat amount calculated by this formula is equivalent to a heat amount applied to the substrate, how much the substrate temperature rises when this heat amount is applied to the substrate may be calculated, thereby identifying the substrate temperature.

In some embodiments, a data logger may be provided in the substrate temperature measurement device M or separately from the substrate temperature measurement device M to allow the above calculations to be automatically performed according to logic implemented on the data logger. In other embodiments, alternatively or additionally, a computer for executing such calculations may be provided. Further, an initial temperature of the substrate may be preliminarily registered in the data logger or in the above computer. The computer may include a memory storing program code which, when executed by the computer, performs the calculation.

In some embodiments, the temperatures of the test piece may be displayed on a monitor.

Thermal conductivity has temperature dependency, so that the thermal conductivity of the test piece 1 may be determined based on a result of the temperature measurement of the test piece 1. For example, data about temperature-dependent thermal conductivity of the test piece 1 may be preliminarily stored in the data logger or the computer used for the calculations, and thermal conductivity values corresponding, respectively, to temperature values measured by the one pair of contact thermometers 5 are read out, and averaged to determine a thermal conductivity value for use during the calculation of the heat amount.

Alternatively, instead of averaging the thermal conductivity values, the measured temperature values may be first averaged, and then a thermal conductivity value corresponding to the averaged temperature value may be read out and used as the thermal conductivity for use during the calculation of the heat amount.

Alternatively, a thermal conductivity value corresponding to one of the measured temperature values of the test piece 1 may be used as the thermal conductivity for use during the calculation of the heat amount, as long as a difference between the measured temperature values falls within a reference range. The reference range may be predetermined.

The above techniques of calculating the amount of heat supplied to the test piece 1 and identifying the substrate temperature based on the calculated heat amount makes it possible to more accurately determine the substrate temperature.

The device body 3 of the substrate temperature measurement device M may be provided with a cooling member 4.

The cooling member 4 may be a hollow cylindrical member which is fitted into the device body 3 and through which a cooling medium flows. The cooling member 4 makes it possible to quickly return the temperature of each of the heat absorbing member 2 and the test piece 1 to an initial temperature thereof, after stopping the heating of the substrate S by the heat source H.

Here, as long as radiant heat of the heat absorbing member 2 heated by the heat source H exerts little influence on the test piece 1, it is enough for the cooling member 4 to have the capability of cooling only the test piece 1.

With regard to the cooling member 4, various other configurations may be employed. For example, a cooling medium flow passage may be directly formed in the device body 3, and/or a cooling jacket may be attached to a side surface of the device body 3.

In FIG. 2, a reflective plate 6 is provided beneath the substrate S. The reflective plate 6 may reflect heat rays transmitted through the substrate S back toward the substrate S, thereby improving substrate heating efficiency.

When the reflective plate 6 is provided, the reflective plate 6 may be provided separately beneath the test piece 1, as depicted in FIG. 2, so as to further reflect heat back toward the test piece 1. With regard to an installation site of the reflective plate 6 for the test piece 1, the reflective plate 6 may be installed with the device body 3 of the substrate temperature measurement device M. Further, instead of the illustrated split-type reflective plate 6 that is provided separately, a large-size reflective plate 6 may be provided beneath the substrate S and the substrate temperature measurement device M, such that both the substrate S and the substrate temperature measurement device M are arranged within a region over which the large-size reflective plate is disposed.

Further, instead of the reflective plate 6, a floor surface of the vacuum chamber C may be covered by a metal thin film capable of easily reflecting heat rays from the heat source having a specific main wavelength.

Depending on position along the surface of the substrate, there is a certain level of temperature difference. Thus, in order to know a temperature distribution along the surface of the substrate, the substrate temperature measurement device M may be provided plurally to measure the substrate temperature.

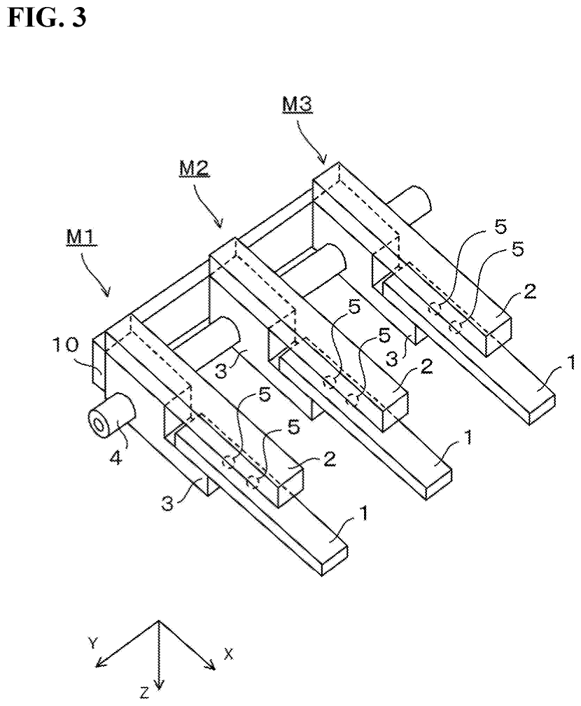

FIG. 3 shows an example of a configuration of an assembly in which a substrate temperature measurement device M is provided plurally, according to an embodiment. As depicted in FIG. 3, a plurality of substrate temperature measurement devices M1 to M3 may be arranged side-by-side along a Y-direction, wherein the substrate temperature measurement devices M1 to M3 are coupled together and assembled in a unified manner by using a single cooling member 4 as a common member. That is, while a coupling member 10 is illustrated in FIG. 3, the coupling member 10 may be omitted in some embodiments.

This assembly makes it possible to measure a temperature distribution in a given direction. Further, the use of the single cooling member 4 as the common member makes it possible to simplify the configuration of the entire assembly.

In the case where the substrate temperature measurement devices M1 to M3 are unified, there is concern that the rigidity of the single cooling member 4 may not be enough to support the substrate temperature measurement devices M1 to M3.

In order to cope with this concern, according to some embodiments, the device bodies 3 of the substrate temperature measurement devices M1 to M3 may be partly coupled together, or a coupling member 10 for coupling the devices together may be additionally provided. In the assembly illustrated in FIG. 3, the devices are coupled together by the coupling member 10.

The configuration in FIG. 3 is intended to measure the temperature distribution of the substrate along the Y-direction. On the other hand, to two-dimensionally measure the temperature distribution along the surface of the substrate, the plurality of substrate temperature measurement devices may also be arranged side-by-side in an X-direction orthogonal to the Y-direction, in addition to the configuration in FIG. 3.

In a case where the substrate temperature is not measured in real time, the substrate temperature measurement device M may be arranged beneath the substrate S, instead of at the periphery of and adjacent to the substrate S.

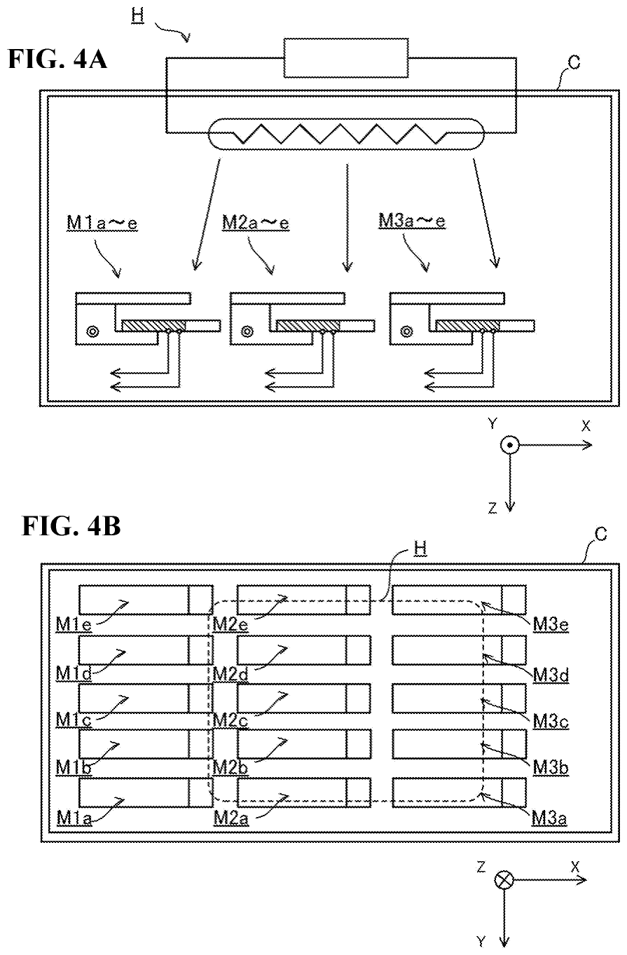

Further, in order to measure a temperature distribution in a position where the substrate is heated, the plurality of substrate temperature measurement devices may be two-dimensionally arranged, as shown in FIGS. 4A and 4B.

FIGS. 4A and 4B are a plan view and a top view, respectively, showing an example in which substrate temperature measurement devices are two-dimensionally arranged, according to an embodiment. It is noted that the substrate S is not shown in FIGS. 4A and 4B for conciseness and clarity.

Here, the illustrated substrate temperature measurement devices M1a to M1e, M2a to M2e, M3a to M3e are coupled together and assembled in a unified manner by non-illustrated coupling members.

The configuration exemplified in FIGS. 4A and 4B is shown and described by way of an example. Embodiments are not limited to the example shown in FIGS. 4A and 4B. When arranging the plurality of substrate temperature measurement devices M1a to M1e, M2a to M2e, M3a to M3e, the plurality of substrate temperature measurement devices M1a to M1e, M2a to M2e, M3a to M3e need not necessarily be oriented in the same direction. That is, various other arrangements may be employed. For example, the substrate temperature measurement devices M1a to M1e may be arranged in opposed in face-to-face relation to the substrate temperature measurement devices M2a to M2e, or the substrate temperature measurement devices M1a to M1e, M2a to M2e, M3a to M3e are arranged in staggered manner in the Y-direction.

Although it is assumed, in the embodiment shown in FIGS. 4A and 4B, that the heat source H has a size enough to sufficiently heat the entire surface of the substrate S, according to some embodiments, the heat source H may include a plurality of small-size heat sources capable of heating the entire surface of the substrate S.

According to some embodiments, the small-size heat sources may be provided by the same number as that of the substrate temperature measurement devices M1a to M1e, M2a to M2e, M3a to M3e as shown in FIGS. 4A and 4B, and configured such that an output of each of the small-size heat sources is adjusted based on the measurement result in a corresponding one of the substrate temperature measurement devices M1a to M1e, M2a to M2e, M3a to M3e.

Alternatively, the number of the small-size heat sources may be set to be different from the number of the substrate temperature measurement devices M1a to M1e, M2a to M2e, M3a to M3e. For example, three heat sources each elongated in the Y-direction may be arranged side-by-side in the X-direction, and each of the heat sources may be disposed in opposed relation to a corresponding one of three sets of the plurality of substrate temperature measurement devices arranged side-by-side in the Y-direction. In this case, based on a value obtained by averaging measurement values from each set of the plurality of substrate temperature measurement devices arranged side-by-side in the Y-direction, the output of a corresponding one of the heat sources may be adjusted.

Alternatively, according to some embodiments, five heat sources each having a length direction in the X-direction may be arranged side-by-side in the Y-direction, and, based on a value obtained by averaging measurement values from each set of the plurality of substrate temperature measurement devices arranged side-by-side in the X-direction, the output of a corresponding one of the heat sources may be adjusted.

The output adjustment for each heat source is described by way of an example. Thus, various other configurations may be employed according to respective numbers of and a positional relationship between the heat sources and the substrate temperature measurement devices.

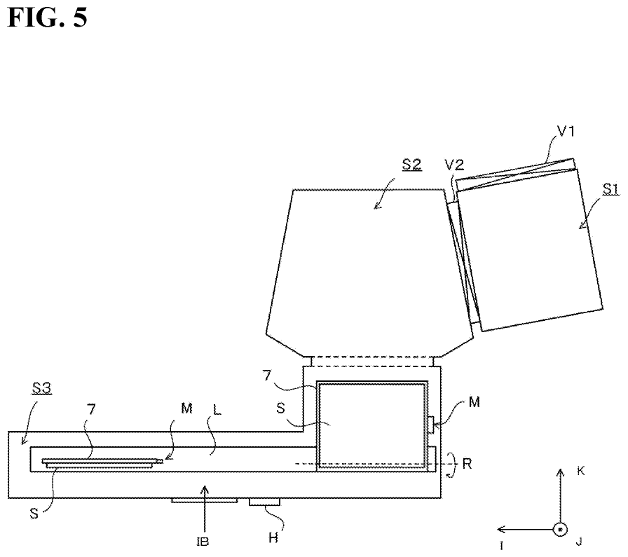

FIG. 5 shows an example of a configuration of an ion implantation apparatus using a substrate temperature measurement device M according to an embodiment. In FIG. 5, the illustration of a beam transport path and the like of the ion implantation apparatus is omitted, because it is assumed that heating of a substrate is performed inside the after-mentioned processing chamber. Conveyance and heating of a substrate in the ion implantation apparatus will be briefly described below.

A substrate S is conveyed to a load-lock chamber S1 by a non-illustrated vacuum robot. At that time, an atmosphere-side valve V1 of the load-lock chamber S1 is in an open state, and a vacuum-side valve V2 of the load-lock chamber S1 is in a closed state.

When the substrate S is conveyed into the load-lock chamber S1, the atmosphere-side valve V1 of the load-lock chamber S1 is closed, and vacuuming of the load-lock chamber S1 is performed.

Then, after the load-lock chamber S1 has a given degree of vacuum, the vacuum-side valve V2 of the load-lock chamber S1 is opened, and the substrate is conveyed from the load-lock chamber S1 to a holding member 7 located in a processing chamber S3 by the non-illustrated vacuum robot located in a substrate conveyance chamber S2.

Then, after the substrate S is conveyed to and held by the holding member 7, the holding member 7 is turned about an R axis by a non-illustrated turning mechanism, and conveyed in an I-direction along a guide rail L to reach a position where the holding member 7 has completely passed across an ion beam IB. In the example illustrated in FIG. 5, in the middle of this substrate conveyance, substrate heating by a heat source H is performed.

The ion beam IB may be a ribbon beam, and may have a J-directional dimension greater than that of the substrate S, and the holding member 7 may be conveyed along the I-direction such that the substrate S completely passes across the ion beam IB once or plural times depending a required amount of ion implantation to the substrate.

The substrate temperature measurement device M may be attached to one side of the holding member 7. As with the substrate S which is heated in the middle of the substrate conveyance, the test piece 1 of the substrate temperature measurement device M which is conveyed together with the substrate S is also heated by the heat source H.

When the substrate temperature measurement device M passes across the heat source H, the temperature measured by the substrate temperature measurement device M and the heat amount may be calculated based on the measured temperature change with time.

For example, in the case where the measured temperature is used as the substrate temperature, a temperature value obtained by averaging temporally-changing values of the measured temperature may be used as the substrate temperature. On the other hand, in the case where the substrate temperature is identified based on the heat amount, a total heat amount to be obtained by passing across the heat source H may be calculated to identify the substrate temperature.

In the example illustrated in FIG. 5, a single substrate temperature measurement device M is provided at a position corresponding to an approximately center of the substrate S. Alternatively, the substrate temperature measurement device M may be provided plurally along one side of the holding member 7. It should be noted here that the “one side of the holding member 7” means a side of the holding member 7 approximately parallel to the J-direction during the substrate conveyance across the ion beam IB.

In addition, the heat source H may also be provided plurally in the J-direction, wherein each of the heat sources H may be associated with a respective one of the substrate temperature measurement devices to allow the output of each of the heat sources H to be adjusted based on a measurement result in a corresponding one of the substrate temperature measurement devices.

When the substrate temperature measurement device M passes across the ion beam IB, a member exposed to the side of the heat source H will be irradiated with the ion beam IB. If such a member (particularly, the test piece 1) is sputtered by the ion beam IB, there arises a concern that accurate temperature measurement is hindered.

For this reason, a shutter member (not shown) may be provided which is configured to cover a to-be-irradiated side of the substrate temperature measurement device M at a timing when the substrate temperature measurement device M is conveyed to a radiation region of the ion beam IB.

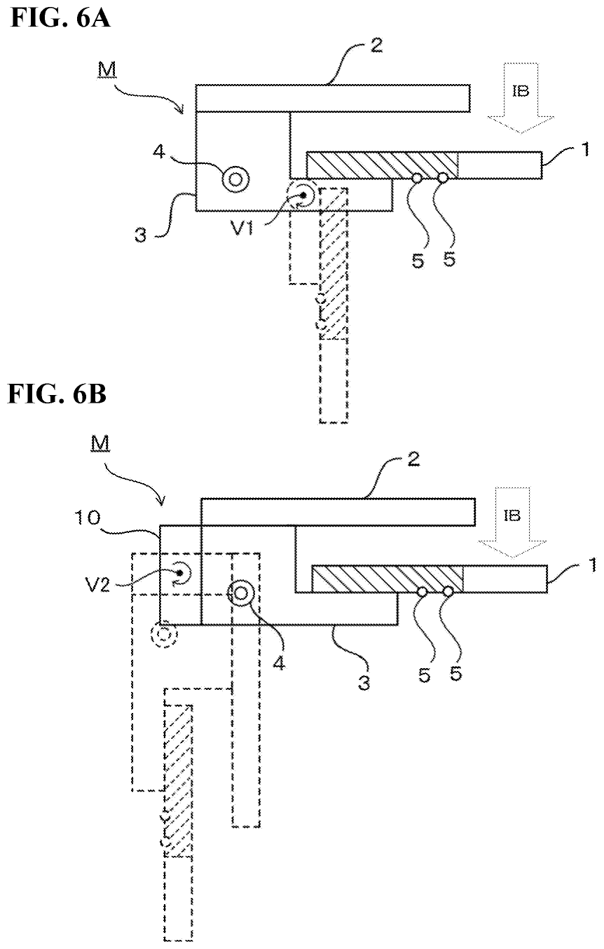

Further, instead of the shutter member, a mechanism as shown in FIGS. 6A and 6B may be employed, according to embodiments. FIGS. 6A and 6B depict two examples of a mechanism for swingably moving a part or an entirety of the substrate temperature measurement device M to prevent the test piece from being sputtered by the ion bean IB.

In the example illustrated in FIG. 6A, a portion of the device body 3 is configured to be swingable about a V1-axis, such that the test piece 1 is swung downwardly (in FIG. 6A) so as to avoid the ion beam IB.

In the example illustrated in FIG. 6B, a coupling member 10 is configured to be rotatable about a V2-axis, such that the test piece 1 is swung downwardly (in FIG. 6B) so as to avoid the ion beam IB without changing a relative position between the heat absorbing member 2 and the test piece 1.

In the mechanism as shown in FIG. 6B which is configured to be free of a change in the relative position between the heat absorbing member 2 and the test piece 1, at least a part of the test piece 1 is always covered by the heat absorbing member 2, so that the heat absorbing member 2 may serve as a protective member for the test piece 1, thereby significantly improving the situation where the test piece 1 is sputtered by the ion beam IB. That is, the heat absorbing member 2 may serve as protective member to protect the test piece 1 from being sputtered by the ion beam IB.

In either case, as long as at least a part of the device body 3 to which the test piece 1 is attached is configured to be swingable, it is possible to prevent the test piece 1 from being sputtered by the ion beam IB.

When viewed from the side of the test piece 1, the heat absorbing member 2 is disposed on the side of the ion beam IB (i.e., toward the ion beam IB as compared to the test piece 1). Thus, the heat absorbing member 2 is unavoidably sputtered unless another member such as a shielding member is disposed.

In a semiconductor manufacturing process using a semiconductor manufacturing apparatus, mixing of a metal into a semiconductor element is undesirable. Therefore, in a case where a substrate temperature measurement device according to various embodiments is applied to a semiconductor manufacturing apparatus, the heat absorbing member 2 is advantageously made of a carbon material, instead of the aforementioned high-melting-point material.

In the ion implantation apparatus, prior to the substrate being heated in the processing chamber S3, preliminary substrate heating may be performed in a substrate conveyance passage other than the processing chamber S3, such as the load-lock chamber S1 or the substrate conveyance chamber S2, so as to quickly raise the substrate temperature to a given value.

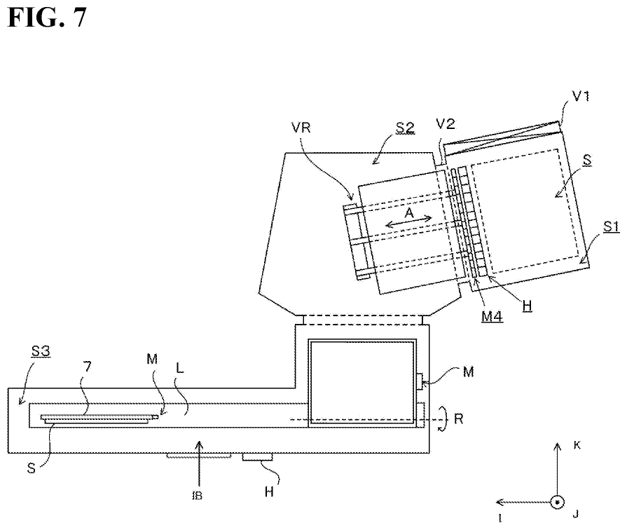

FIG. 7 shows an example of a configuration in which preliminary substrate heating is performed in a load-lock chamber S1, according to an embodiment. A plurality of heat sources H may be arranged on the ceiling of the load-lock chamber S1. A vacuum robot VR is operated such that a handle thereof is reciprocatingly moved in directions indicated by the double-arrowed line A to allow a substrate S supported by the handle to pass across the heat sources H once or plural times.

In FIG. 7, where an element or component sharing a common reference designator with FIG. 5 is the same as that in FIG. 5, its description will be omitted here.

The substrate temperature measurement device M4 according to the embodiment shown in FIG. 7 may be attached to a distal end of the handle of the vacuum robot VR. The substrate temperature measurement device M4 may be reciprocatingly conveyed between the load-lock chamber S1 and a substrate conveyance chamber S2 across the heat sources H, together with the substrate S supported by the handle.

The substrate temperature measurement device M4 may be attached plurally, correspondingly to the plurality of heat sources H, in a direction parallel to an arrangement direction of the heat sources H, as illustrated in FIG. 7. Alternatively, the number may be one.

Further, with regard to adjustment of the output of each heat source based on the measurement result in a corresponding one of the substrate temperature measurement devices M4, the same techniques as those mentioned above may be employed.

Further, the substrate temperature measurement device M4 may be disposed on the side of a base end of the handle opposite to the distal end.

In FIGS. 5 and 7, the description has been made by taking the ion implantation apparatus as an example. However, the substrate temperature measurement device according to various embodiments may be applied to not only the ion implantation apparatus but also various other semiconductor manufacturing apparatuses such as a sputtering apparatus and a film forming apparatus.

Further, the description has been made by taking as an example the configuration in which the substrate S passes across an ion beam. This configuration is common in the ion implantation apparatus and various other ion beam irradiation apparatuses such as an ion beam etching apparatus and an ion beam orientation apparatus. Thus, the example of the configuration of the substrate temperature measurement device described with reference to FIG. 5 or FIG. 7 may be directly applied to the other ion beam irradiation apparatuses.

FIGS. 5 and 7 show configurations in which the substrate temperature measurement device M is conveyed together with the substrate S. Alternatively, the substrate temperature measurement device M may be fixed at a position where the substrate is heated.

In this case, it becomes more difficult to measure the substrate temperature during the period during which the substrate is heated by the heat source, as with the example in FIG. 4. However, the various embodiments herein do not exclude such a usage mode.

In the configuration illustrated in FIG. 5, the substrate temperature measurement device M is attached to one side of the holding member 7. Alternatively, the substrate temperature measurement device M may be attached to another member which is provided separately from the holding member 7.

In this case, in conjunction with conveyance of the holding member 7, the substrate temperature measurement device M may be conveyed along the same guide rail as that for the holding member 7, or along another guide rail provided to extend parallel to the guide rail for the holding member 7.

In the above embodiments, it is assumed that the heat source H is disposed inside the vacuum chamber C. However, a disposition location of the heat source H is not limited thereto.

For example, the substrate inside the vacuum chamber may be heated by the heat source H which is disposed outside the vacuum chamber, through a dielectric window provided in the wall of the vacuum chamber C.

As a measure against sputtering of the test piece 1 by the ion beam IB, the mechanism for swingably moving at least a part of the device body 3 has been described based on FIG. 6. Additionally, the device body 3 may be configured to be partly or entirely swung in a situation other than during exposure to the ion beam IB.

For example, considering degradation of the test piece, it is undesirable that the non-overlap region of the test piece is continued to be exposed to the heat source. Therefore, the device body 3 may be configured to be swingably moved as shown in FIG. 6A or 6B to allow the test piece 1 to move away from the heat source H when temperature measurement is not performed.

In the example illustrated in FIG. 7, the description has been made based on the configuration in which the substrate supported by the handle of the vacuum robot VR is reciprocatingly moved between the load-lock chamber S1 and the substrate conveyance chamber S2, thereby performing the preliminary substrate heating. Alternatively, the preliminary substrate heating may be performed by reciprocatingly moving the substrate in a different location therefrom.

For example, the preliminary substrate heating may be performed by reciprocatingly moving the substrate between the substrate conveyance chamber S2 and the processing chamber S3 or within only the substrate conveyance chamber S2. That is, consistent with the various embodiments disclosed here, the inventive concept may be applied even if the preliminary substrate heating is performed in any location of the substrate conveyance passage.

The above embodiments have been described based on an example where one pair of contact thermometers are used. However, the number of the pairs is not limited to one, but two or more pairs of thermometers, such as two pairs of thermometers or three pairs of thermometers, may be used.

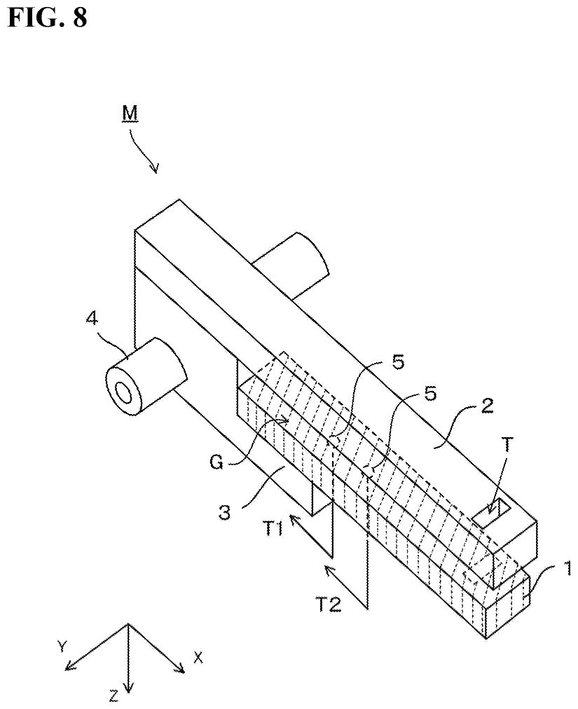

FIG. 8 shows the configuration of a substrate temperature measurement device M according to an embodiment. In the substrate temperature measurement device M illustrated in FIG. 8, a heat absorbing member 2 is disposed to entirely cover a test piece 1, wherein the test piece 1 is partly exposed to the heat source H through a through-hole T formed in the heat absorbing member 2. The substrate temperature measurement device M of FIG. 8 may have the same advantageous effects as described above with respect to the embodiments of FIGS. 1-7.

It should be understood that the present disclosure is not limited to the above embodiments, but various other changes and modifications may be made therein without departing from the spirit and scope of the appended claims.

What is claimed is:

1. A device comprising:
a test piece having a thermal transmissivity approximately equal to that of a substrate;
a device body to which the test piece is attached; and
a heat absorbing member attached to the device body in spaced-apart relation to the test piece in a first direction,
wherein the test piece has an overlap region which overlaps the heat absorbing member in the first direction, and a non-overlap region which does not overlap the heat absorbing member in the first direction,
and wherein the non-overlap region is exposed to a heat source, and the overlap region has a contact thermometer attached thereto.

2. The device as recited in claim 1, wherein the contact thermometer comprises at least one pair of contact thermometers.

3. The device as recited in claim 1, further comprising a cooling member provided in the device body, the cooling member cooling the test piece.

4. The device as recited in claim 1, wherein the device body is configured to be swingable.

5. An apparatus comprising:
a heat source that heats a substrate during conveyance in a conveyance direction within a conveyance passage through which the substrate is conveyed; and
a plurality of the device of claim 1, which are disposed to receive heat from the heat source, and are arranged side-by-side in the conveyance direction.

6. An apparatus comprising:
a heat source that heats a substrate during conveyance;
a holding member that holds the substrate and is conveyed in a given direction across the heat source; and
the device of claim 1,
wherein the device is configured to be conveyed across the heat source together with the holding member.

7. A device comprising:
a body;
a heat absorber attached to the body;
a piece attached to the body and spaced apart from the heat absorber, the piece having an overlap region that is overlapped by the heat absorber such that the heat absorber absorbs heat radiated toward the device and a non-overlap region which does not overlap with the heat absorber and which is exposed to the heat radiated toward the device; and
a contact thermometer coupled to the overlap region,
wherein the piece has a thermal transmissivity approximately equal to that of a substrate, and
the device is configured to position the overlap region of the piece adjacent to the substrate being radiated by the heat.

8. The device as recited in claim 7, wherein the contact thermometer comprises at least one pair of contact thermometers.

9. The device as recited in claim 7, further comprising a cooling member provided in the body, the cooling member cooling the piece.

10. The device as recited in claim 7, wherein the body is configured to be swingable to position the overlap region of the piece adjacent to the substrate.
